(19) United States
(12) Patent Application Publication
(10) Pub. No.: US 2024/0164072 A1
(43) Pub. Date: May 16, 2024

(54) MICRO DISPLAY THERMAL MANAGEMENT SYSTEM

(71) Applicant: Vuzix Corporation, West Henrietta, NY (US)

(72) Inventors: Robert J. Schultz, Victor, NY (US); Devrin C. Talen, Rochester, NY (US)

(21) Appl. No.: 18/511,512

(22) Filed: Nov. 16, 2023

Related U.S. Application Data
(60) Provisional application No. 63/426,014, filed on Nov. 16, 2022.

(51) Int. Cl. H05K 7/20; G02B 6/34; G02B 27/01

(52) U.S. Cl. CPC H05K 7/20954; G02B 6/34; G02B 27/0172; G02B 2027/0178

(57) ABSTRACT

An augmented reality near-eye display system including an image source system operable to generate image-bearing light beams, the image source system including a plurality of individually addressable components, a temperature sensor operable to detect a temperature within the image source system, and a processor and non-transitory computer-readable memory configurated to execute and store a set of computer-readable instructions that when executed by the processor are configured to selectively drive each of the plurality of individually addressable components based on the temperature of the image source system.

### TECHNICAL FIELD

The present disclosure relates to thermal management of compact display systems, particularly such systems designed to produce virtual images by micro display engines configured and arranged for near-eye viewing within a head-mounted display (HMD).

### BACKGROUND

Augmented reality systems, which add virtual images to an individual's otherwise unobstructed field of view (FOV), are featured in applications ranging from enterprise to defense to entertainment. Various attempts have been made to produce portable (wearable) devices, such as glasses or safety goggles, capable of presenting high resolution, dynamic digital information within the user's unobstructed field of view of the world. Environments with high ambient light intensity present additional challenges. Whether for HMD applications or full mixed and augmented reality training simulations, small, inexpensive, ruggedized solutions are needed.

HMDs may utilize one or more image source systems when generating image content. For example, HMDs may utilize technology conventionally referred to as a projector, e.g., a Liquid Crystal Display (LCD), a Liquid Crystal on Silicon (LCoS) display, or a Digital Light Processing (DLP) display. Each of these image source systems can utilize one or more light sources, usually Light Emitting Diodes (LEDs) or Organic LEDs (OLEDs) to generate monochromatic or polychromatic light that will be modulated by each display system. As each of these image source systems modulates light created by a separate source, these types of systems are sometimes also referred to as Spatial Light Modulators (SLMs) or attenuating projectors. Transmissive spatial light modulators, e.g., LCD display systems, can be optically inefficient thereby increasing power requirements of the light source. Consequently, illumination sources such as LED's must be driven with higher currents, increasing power consumption and heat production. Reflective spatial light modulators such as LCoS or DLP displays can be optically more efficient and are used in a number of applications such as digital projectors. However, because these systems modulate incident light rather than emit light directly, they require additional optics that project, condense, and split output beams from the LED sources. Additionally, because these image source systems only modulate incident light, the light source must remain turned on regardless of image content. For example, a bright full-screen virtual image and a simple arrow that takes up only 5% of the display pixels will consume approximately the same power.

Alternatively, HMDs may utilize an image source system comprising a self-emitting display projector when generating image content. Self-emitting displays may include an array of LEDs or OLEDs that generate a collective image by turning on, off, or dimming respective LEDs. However, self-emitting display systems are still prone to overheating, which can distort the image presented to the user, damage internal components of the HMD, or create discomfort for the user of the HMD.

One way to reduce the risks associated with overheating is to uniformly dim the image source system. This method involves reducing the brightness across all of the image source system uniformly. This method, however, is not desirable for augmented reality systems (e.g., HMDs and HUDs), as the reduced brightness will reduce contrast with the view of the world. The dimmed screen would maintain its own internal contrast, i.e., adjacent pixels would maintain a contrast relationship because they would maintain the same relative brightness, but the view of the world would not undergo a commensurate reduction in brightness, so the user would ultimately suffer a reduced contrast between the dimmed image overlay and the consistently bright view of the world.

Similarly, overall power usage can also be of concern. For example, when a power source, e.g., a battery, is below a certain threshold of stored power, it may be desirable to alter certain aspects of the image source system to conserve remaining battery power and minimize power consumption.

For these reasons, an improved microdisplay system with a thermal management system that maximizes display contrast, while minimizing battery usage and risk of overheating is necessitated.

### SUMMARY

The present disclosure provides an augmented reality near-eye display system comprising an image source system operable to generate image-bearing light beams, the image source system comprising a plurality of individually addressable image light sources, a temperature sensor operable to detect a temperature within the image source system, a processor and non-transitory computer-readable memory configured to execute and store a set of computer-readable instructions that when executed by the processor are configured to selectively drive each of the plurality of individually addressable image light sources based on the temperature of the image source system.

The present disclosure further includes a method of thermal control of an augmented reality near-eye display system, the method comprising the steps of generating images with an image source system, the image source system comprising a plurality of individually addressable image light sources, detecting a first temperature within the image source system, and adjusting power applied to a first set of the plurality of individually addressable image light sources when the first temperature of the image source system is above a predetermined threshold to modulate light emitted from a first set of pixels corresponding to the first set of the plurality of individually addressable image light sources, whereby heat generation by the image source system is reduced.

With augmented reality display systems, there is an increased importance for adaptable brightness of the virtual image. This is because the image source system, for example, a projector or a self-emitting microdisplay, can generate high temperatures as a result of electrical energy used by the image source system as well as energy absorbed from other light generating components of the image source system. For example, in a self-emitting microdisplay system, each of the individually addressable components used to generate the desired images may receive electrical current—generating heat—and may produce light (which may be absorbed and re-radiated by other components) generating additional heat. These high temperatures can damage the optical elements and other internal components of the augmented reality display system. Overheating of the image source system can also lead to early failure of the projector, self-emitting display, or other parts of the image source system, and can lead to distortion of the images presented to the user and/or be physically uncomfortable for the user of an augmented reality system.

In one example embodiment of the present disclosure, the image source system can be a self-emitting display, such as an LED or OLED display. LED and OLED displays include an array of individually addressable LED components which each emit light at an individual brightness value. Each LED is an individual light source, and each LED can be dimmed or turned off completely (i.e., not emitting any light) without affecting any adjacent LED.

In another exemplary embodiment of the present disclosure, the image source system is a projector, for example, an LCD projector, a LCoS projector, or a DLP projector. Each projector includes a light source, e.g., one or more LEDs arranged to generate monochrome or polychromatic light. In these examples, these projectors may include one or more subsystems arranged to spatially modulate the light generated by the light source(s) to generate images viewable by the user of the system.

In another example embodiment the image source system is a part of a larger optical system where the image-bearing light produced by the image source system is directed to and is incident upon an image light guide operable to convey the image-bearing light along a transmissive imaging light guide substrate from a location outside the viewer's field of view to a position in alignment with the viewer's pupil while preserving the viewer's view of the environment through the image light guide. In an example embodiment, collimated, relatively angularly encoded light beams from the image source system are coupled into a transparent planar image light guide by an in-coupling diffractive optic, which can be mounted or formed on a surface of the image light guide or buried within the image light guide. Such diffractive optics can be formed as diffraction gratings, holographic optical elements or in other known ways. After propagating along the image light guide, the diffracted light can be directed back out of the image light guide by an out-coupling diffractive optic, which can be arranged to provide pupil expansion along at least one dimension of a virtual image generated by the system. In addition, a turning diffractive optic (or intermediate diffractive optic) can be positioned along the image light guide optically between the in-coupling and out-coupling diffractive optics to provide pupil expansion in one or more dimensions. Two dimensions of pupil expansion define an expanded eyebox within which the viewer's pupil can be positioned for viewing the virtual image conveyed by the image light guide. The image light guide comprises an optically transparent material which allows a user to see both the virtual image generated by the near-eye display and the real-world view simultaneously.

### BRIEF DESCRIPTION OF THE SEVERAL VIEWS OF THE DRAWINGS

The accompanying drawings are incorporated herein as part of the specification. The drawings described herein illustrate embodiments of the presently disclosed subject matter and are illustrative of selected principles and teachings of the present disclosure. However, the drawings do not illustrate all possible implementations of the presently disclosed subject matter and are not intended to limit the scope of the present disclosure in any way.

FIG. 1 is a perspective view of an augmented reality near-eye display for mounting on a viewer's head.

FIG. 2 is a schematic top view of binocular image light guides according to FIG. 1.

FIG. 3A is a schematic side view of an image source system according to an embodiment of the present disclosure.

FIG. 3B is a schematic top plan view of a light source according to FIG. 3A.

FIG. 4A is a schematic side view of an image source system according to an embodiment of the present disclosure.

FIG. 4B is a schematic top plan view of a portion of the image source system according to FIG. 4A.

FIG. 5A is a schematic perspective view of an image source system according to an embodiment of the present disclosure.

FIG. 5B is a schematic detail view of a portion of the image source system according to FIG. 5A.

FIG. 5C is a schematic perspective view of a portion of the image source system according to FIG. 5A in a first state.

FIG. 5D is a schematic perspective view of a portion of the image source system according to FIG. 5C in a second state.

FIG. 6A is a schematic perspective view of an image source system according to an embodiment of the present disclosure.

FIG. 6B is a cross-sectional view of a portion of the image source system according to FIG. 6A.

FIG. 7 is a cross-sectional view of a portion of an image light guide h and an image source system.

FIG. 8 is an example of a series of landing page display images wherein the features of the landing pages are overlayed on a white background representing unilluminated pixels of the display.

FIG. 9 is another example of a landing page wherein the features of the landing page are overlayed on a white background representing unilluminated pixels of the display.

FIG. 10 shows an embodiment of a mitigation protocol of the present disclosure in application with the “Home” label element of a home screen landing page.

FIG. 11 shows another mitigation protocol in application with the “Home” label.

FIG. 12 shows another mitigation protocol in application with the “Home” label.

FIG. 13 is another embodiment of a mitigation protocol in application with the “Home” label.

FIG. 14 is a flow chart showing an example method of thermal control of an augmented reality near-eye display system of the present disclosure.

FIG. 15 is a flow chart showing an example embodiment of a method mitigating an undesired level of energy output in an augmented reality near-eye display system.

### DETAILED DESCRIPTION

It is to be understood that the invention may assume various alternative orientations and step sequences, except where expressly specified to the contrary. It is also to be understood that the specific assemblies and systems illustrated in the attached drawings and described in the following specification are simply exemplary embodiments of the inventive concepts defined herein. Hence, specific dimensions, directions, or other physical characteristics relating to the embodiments disclosed are not to be considered as limiting, unless expressly stated otherwise. Also, although they may not be, like elements in various embodiments described herein may be commonly referred to with like reference numerals within this section of the application.

Where they are used herein, the terms “first”, “second”, and so on, do not necessarily denote any ordinal, sequential, or priority relation, but are simply used to more clearly distinguish one element or set of elements from another, unless specified otherwise.

Where they are used herein, the terms “viewer”, “operator”, “observer”, and “user” are considered to be equivalent and refer to the person who views the virtual images through a near-eye viewing device.

Where used herein, the term “projector” refers to an optical device that emits image-bearing light, and can include additional optical components beyond the display or display panel, e.g., collimating/focusing optics.

Where used herein, the term “about” when applied to a value is intended to mean within the tolerance range of the equipment used to produce the value, or, in some examples, is intended to mean plus or minus 10%, or plus or minus 5%, or plus or minus 1%, unless otherwise expressly specified.

Where used herein, the term “substantially” is intended to mean within the tolerance range of the equipment used to produce the value, or, in some examples, is intended to mean plus or minus 10%, or plus or minus 5%, or plus or minus 1%, unless otherwise expressly specified.

Where used herein, the term “exemplary” is intended to mean “an example of,” “serving as an example,” or “illustrative,” and does not denote any preference or requirement with respect to a disclosed aspect or embodiment.

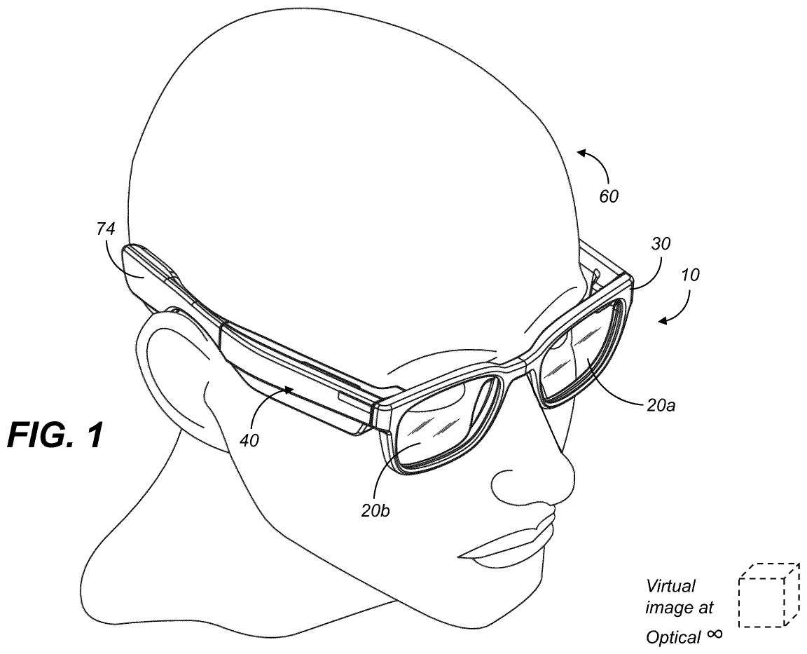

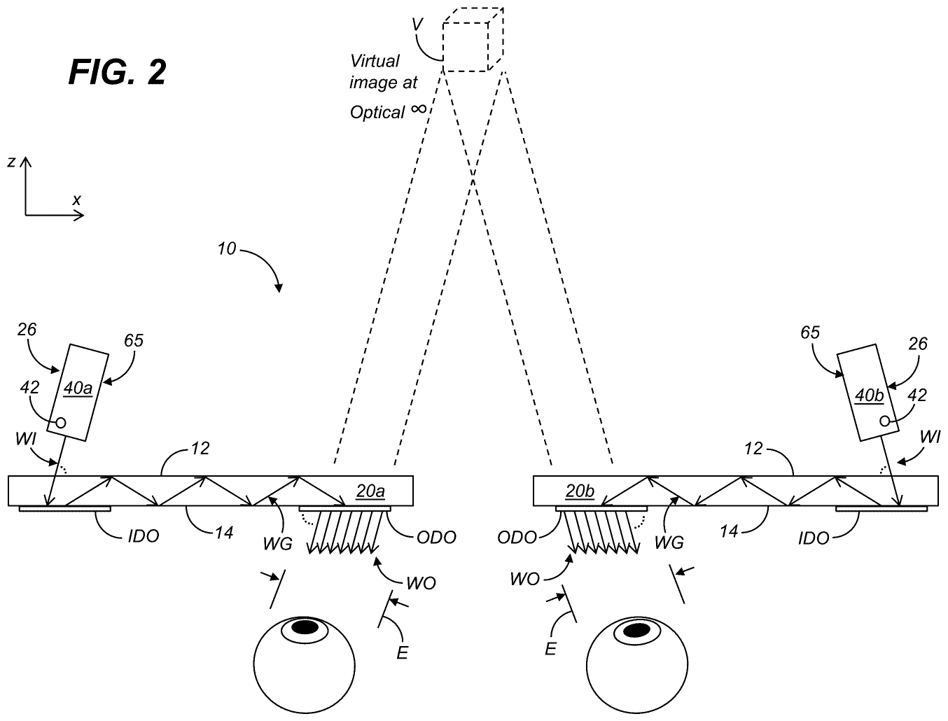

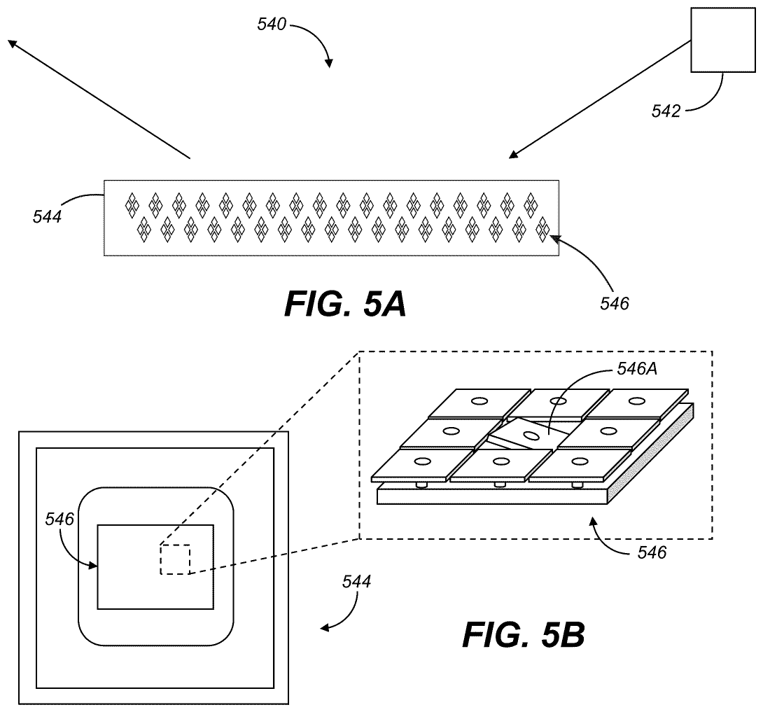

Referring now to the figures, FIG. 1 illustrates one example embodiment of an augmented reality near-eye display system 10 for mounting on a viewer's head according to the present disclosure. Augmented reality near-eye display system 10 includes image source systems 40 (e.g., image source systems 40a and 40b as shown in at least FIG. 2) and associated drive electronics 65 and memory 85 (as shown in FIG. 7), each mounted along a temple member 74 of a frame of augmented reality near-eye display system 10, where the augmented reality near-eye display system takes the form of glasses 30. Although augmented reality near-eye display system 10 is illustrated as a binocular system, i.e., a system with an image source system for the left eye and a second image source for the user's right eye, respectively, it should be appreciated that the present disclosure applies equally to monocular systems, i.e., systems with only one image source system for either the user's left or right eye. Similarly, although augmented reality near-eye display system 10 is illustrated as a “smart glasses” system, it should be appreciated that the present disclosure applies equally to Heads-Up Displays (HUDs) with different positioning of the image source system 40 and associated drive electronics 65, memory 85, and processor 75. The glasses 30, in one example embodiment, are configured in such a way to resemble conventional eye-wear (e.g., ophthalmic eyeglasses). In an example embodiment, the image source systems 40a, 40b (collectively referred to herein as “image source systems 40” or in the singular as “image source system 40”) include one or more projectors, e.g., an LCD, LCoS, or DLP projector system that is energizable to emit a respective set of angularly related beams. In another example embodiment the image source systems 40 each comprise a self-emitting micro display that includes a plurality of individually addressable image light sources, e.g., LEDs or OLEDs. In one example, the plurality of individually addressable light sources form a two-dimensional array of semiconductor micro LEDs (uLEDs).

FIG. 2 is a schematic top view of one example embodiment of augmented reality near-eye display system 10 with binocular image light guides 20a, 20b (collectively referred to herein as “image light guides 20” or in the singular as “image light guide 20”) where the frames of the glasses 30 have been removed for clarity. Each image light guide 20 includes plane-parallel front and back surfaces 12 and 14, an in-coupling diffractive optic DO, and an out-coupling diffractive optic ODO. In an example embodiment, as illustrated in FIG. 2, incoming beam WI of image-bearing light, which represents one of many angularly related beams required to convey an image, and which is generated by one of the respective image source systems 40, transmits through the front surface 12 of the respective image light guide 20 and is diffracted by a reflective-type, in-coupling diffractive optic IDO located on the back surface 14 of the image light guide 20. As such, the in-coupling diffractive optic IDO, which can be arranged as a reflective-type diffraction grating, redirects a portion of the incoming beam WI into the image light guide 20 for further propagation along the image light guide 20 as guided beam WG via total internal reflection (TIR).

The guided beam WG propagates along the depicted x-axis of the image light guide 20 by the mechanism of total internal reflection (TIR) between the plane-parallel front and back surfaces 12, 14 toward the out-coupling diffractive optic ODO. The out-coupling diffractive optic ODO outputs at least a portion of the image-bearing light WG incident thereon as outgoing beam WO. The plurality of angularly encoded light beams of collimated light represented by the outgoing beam WO form a virtual image focused at optical infinity (or some other fixed focal distance) by conveying the angularly encoded light beams to the viewer eyebox E. In an example embodiment, the out-coupling diffractive optic ODO is operable to replicate, at least a portion of, image-bearing light incident thereon in one or more dimensions, providing an expanded eyebox E. In one example embodiment, the image source systems 40 are attenuating projectors (such as those described above), or a self-emitting display projector that can be energizable to generate a separate image for each eye, formed as a virtual image with the needed image orientation for upright image display. The images that are generated can be a stereoscopic pair of images for 3-D viewing. The virtual image that is formed by the optical system can appear to be superimposed or overlaid onto the real-world scene content seen by the viewer.

Each of the image source systems 40 further includes a thermal management system 26, which includes a temperature sensor 42 that determines the temperature of the image source system 40. In an example embodiment, the temperature sensor 42 is a thermistor attached to or disposed within a housing of each image source system 40. In another example embodiment, the thermistor 42 is positioned on, in, or proximate to the light sources and/or the individually addressable components, and/or between those components and the other optical components of the image source system 40 within the image source system housing. Thermistors provide resistance within a circuit and react to temperature such that, when the temperature increases, the thermistor provides reduced resistance. If a thermistor is in an environment with variable temperature, it can be used to determine the temperature of the environment based on the corresponding variable resistance exhibited by the thermistor at a given time. Using known methods in the art, the resistance of a thermistor in substantially the same temperature environment as the image source systems 40 can be used to determine the temperature of the image source systems 40, and a processor 75 (shown in FIG. 7) can be programmed to read the resistance data coming from the thermistor. The resistance data corresponding to the temperature of the thermistor's environment is referred to herein as a “signal.”

In an example embodiment, the thermistor or multiple thermistors are integrated into the electronics 65 of each of the image source systems 40, or are otherwise in the same temperature environment of the image source systems 40, such that the temperature of one of the thermistors is able to measure the temperature of one of the image source systems 40. It should be appreciated that, in one or more example embodiments, one or more thermistors are provided for each image source system 40 and that one or more thermistors may be placed directly on a shared Printed Circuit Board (PCB) that includes the image light sources or placed adjacent to PCB that includes the light sources of each image source system 40. The thermistor or multiple thermistors are also in electronic communication such that the processor 75 can receive the signal from the thermistor.

In one example embodiment, the augmented reality near-eye display system 10 includes an image light guide 20 with a forward-facing image source system conveying a virtual image V seen at infinity within a viewer's field of view. In this example embodiment, the projector 40 is positioned frontward-facing with respect to viewer 60 (shown in FIG. 1). In order to achieve angular congruence between incoming beam WI and outgoing beam WO, an additional assistive optical element, including, but not limited to, a mirror, dove prism, fold prism, pentaprism or a combination of the like may be operable to reflect incoming beam WI toward in-coupling diffractive optic IDO (shown as reflected incoming beam WI2) from the requisite rearward facing direction. A mounting apparatus may be operable to secure the assistive optical element and the two-dimensional image source system 40 in relationship with each other, independent of the presence or orientation of the image light guide 20. It should also be appreciated that augmented near-eye display system 10 can include rearward-facing image source systems without the need for an additional assistive optical element. In those examples, the in-coupling diffractive optic IDO and outcoupling diffractive optic ODO can be formed as a reflective or transmissive-type diffraction optic in an arrangement that results in the propagation of out-coupled angularly related beams forming a virtual image within eyebox E.

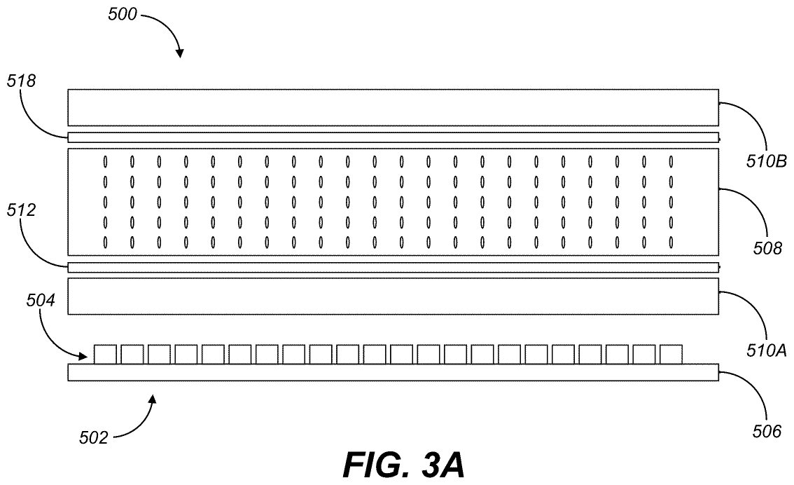

As illustrated in FIGS. 3A-3B, in an example embodiment, the image source system 40 is an LCD projector 500 (e.g., a thin-film-transistor LCD). The LCD projector 500 (also referred to herein as “LCD 500”) includes a light source subsystem 502 having a plurality of LEDs 504 (or OLEDs) arranged on a printed circuit board (PCB) 506 to generate monochrome or polychromatic or white light. In some examples, the plurality of LEDs 504 are white LEDs or OLEDs. The LCD 500 also includes a liquid crystal layer 508 arranged between two polarizers 510A, 510B (e.g., polarizing films). The polarizers 510A, 510B, for example, may have polarization axes generally crossed relative to one another (e.g., polarizer 510B oriented at 90° relative to polarizer 510A). The first polarizer 510A may be arranged between the light source 502 and the liquid crystal layer 508. In an example embodiment, the LCD projector 500 further includes a thin-film-transistor 512 arranged between the first polarizer 510A and the liquid crystal layer 508. It should be appreciated that the LCD projector 500 may also include a color filter 518 (e.g., an RGB color filter). Referring now to FIG. 3B, the thin-film-transistor 512 includes a transparent substrate 514 and a plurality of individually addressable components 516 arranged thereon. Each of the individually addressable components 516 may be a portion of the thin-film transistor 512 that corresponds to a pixel or a portion of a pixel within an image generated by the LCD projector 500. As will be apparent to persons skilled in the relevant arts, one or more elements of the LCD 500 have been omitted to increase clarity of the presently disclosed subject matter.

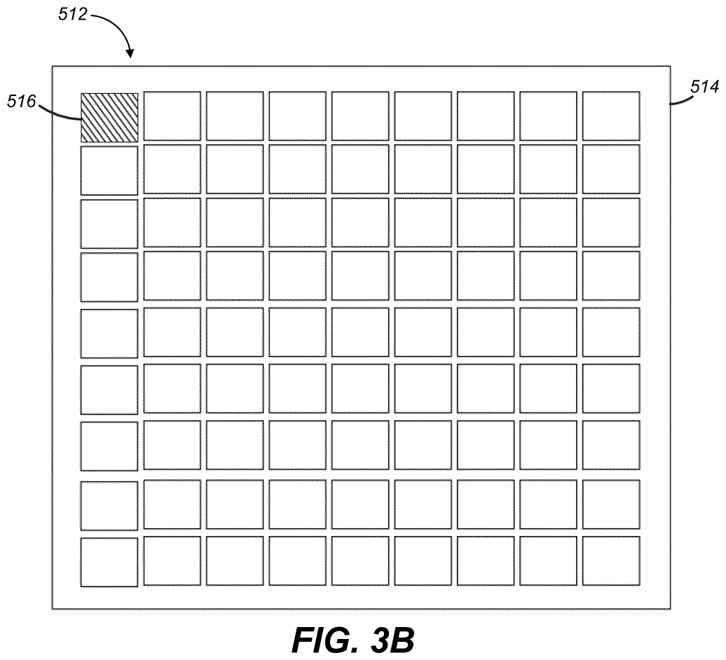

As illustrated in FIGS. 4A-4B, in an example embodiment, the image source system 40 is an LCoS projector 520. The LCoS projector 520 (also referred to herein as “LCoS display 520”) includes a light source 522; for example, a plurality of LEDs or OLED arranged on a PCB to generate monochromatic, polychromatic light, or white light. The LCoS display 520 also includes a polarizer 524 (e.g., polarizing film), a waveplate 526 (e.g., a quarter waveplate), a liquid crystal layer 528, a thin-film-transistor 530 (e.g., a thin-film transistor layer), and a reflective backplate 532. Light emitted by the light source 522 is incident on the polarizer 524. The polarized light is then rotated by the waveplate 526 before the light is incident upon the liquid crystal layer 528. The polarized and rotated light is transmitted through the liquid crystal layer 528 and reflected by the reflective backplate 532. As shown in FIG. 4B, the thin-film-transistor 530 includes a transparent substrate 534 and a plurality of individually addressable components 536 arranged thereon. In an example embodiment, each of the individually addressable components 536 may be a portion of thin-film transistor 512 that corresponds to a pixel or a portion of a pixel of an image generated by the LCoS display 520. In another example embodiment, a plurality of individually addressable components 536 correspond to a single pixel of an image generated by the LCoS display 520. Without rotation of the light reflected from the reflective backplate 532 by the liquid crystal layer 528, the polarizer 524 is configured to block the light reflected from the reflective backplate 532. As will be apparent to persons skilled in the relevant arts, one or more elements of the LCoS display 520 have been omitted to increase clarity of the presently disclosed subject matter.

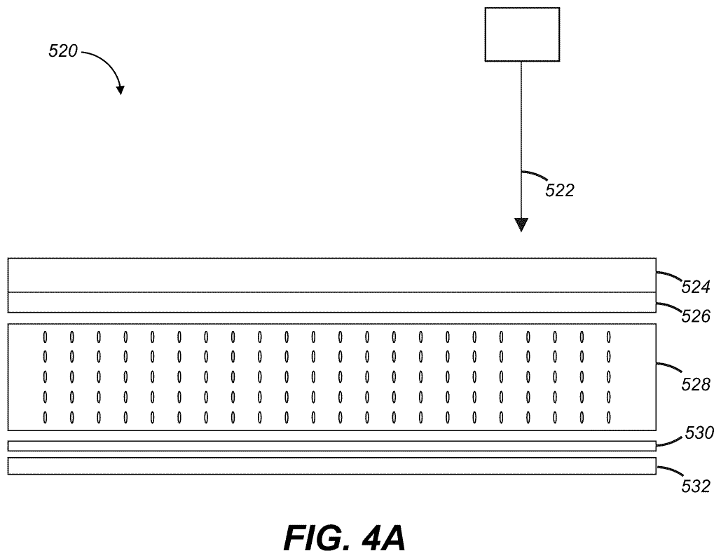

As illustrated in FIGS. 5A-5D, in another example embodiment, the image source system 40 is a DLP display projector 540. The DLP display projector 540 (also referred to herein as “DLP display 540”) includes a light source 542; for example, without limitation, a plurality of monochromatic or polychromatic LEDs, one or more lasers, or a white light and color wheel. The DLP display 540 further includes a digital micromirror device (DMD) 544 having an array of micromirrors 546 configured to be positioned (e.g., rotated) between an ON and OFF state. Each micromirror 546 is an individually addressable component of the DLP display 540. For example, as shown in FIGS. 5B and 5D, one or more micromirrors 546A of the DMD 544 can be arranged in an ON position to reflect a portion of light from the light source 542 toward an optical component such as a lens 548. As shown in FIG. 5C, micromirrors 546 arranged in an OFF position reflect a portion of light form the light source 542 towards and light dump 550 (e.g., a heat sink and/or light absorber). For example, electrodes control the position of the micromirrors 546 via electrostatic attraction. In some examples each micromirror 546 corresponds to one or more pixels in a projected image.

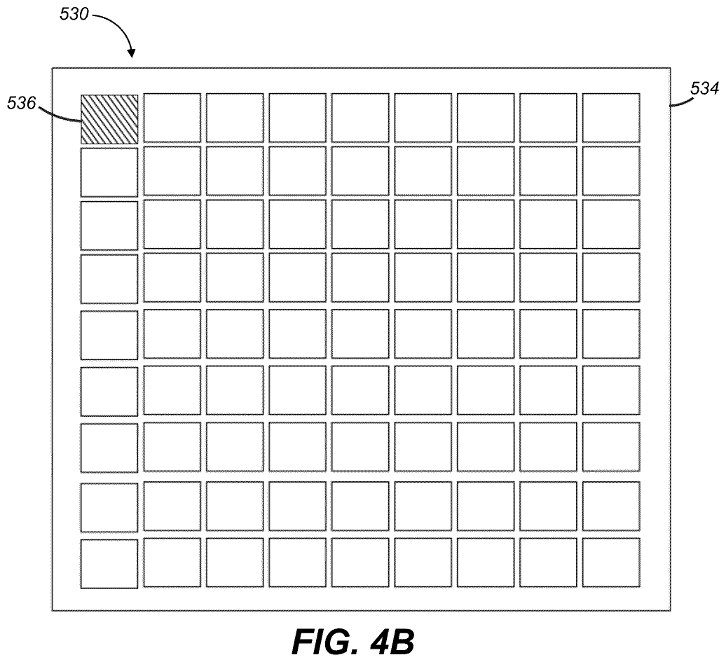

As illustrated in FIGS. 6A and 6B, in another example embodiment, the image source system 40 is a self-emitting microLED display projector that includes a self-emitting microLED display panel 560. For example, as illustrated in FIG. 6B, which illustrates a cross-sectional view of a portion of the self-emitting microLED display panel 560 shown in FIG. 6A, the self-emitting microLED display panel 560 includes a substrate 562, an electrode layer 564 a microLED/OLED array 566, and a front layer 568. Each microLED 566R, 566G, 566B is an individually addressable component of the self-emitting microLED display panel 560. Each microLED 566R, 566G, 566B corresponds to one or more pixels in a projected image. In an example embodiment, the microLED array 566 is configured to emit light as a function of power applied to each self-emitting light source. For example, the microLED array 566 can roughly approximate the size and shape of the in-coupling diffractive optic IDO.

FIG. 7 is a cross-sectional view of a portion of the image light guide 20 having an in-coupling diffractive optic IDO and the image source system 40. In an example embodiment, the image source system 40 includes positive imaging optics 43 and an optional folded optics mirror 44. In an example, the image source system 40 is supported by a portion of the frames of the glasses 30 and in close proximity (e.g., within 5 cm) of one of the front and back surfaces of the imaging light guide 20. Folded optics mirror 44 is an optional feature that can be included to reduce the dimensions of the image source system 40. Depending on imaging requirements, imaging optics 43 can include a positive singlet, a doublet, and/or have additional elements, as well as elements corrected for chromaticity. For example, the focal length of the imaging optics 43 may be chosen such that the projectors 500, 520, 540, 560 are arranged at approximately the focal plane of the imaging optics 43. FIG. 7 shows the image source system 40 where image-bearing light WI is normal to a planar surface of the imaging light guide 20; however, in some example embodiments, image-bearing light WI is positioned at an angle from normal incidence.

In an example embodiment, the image source system 40 includes a thermal management system 26, which includes a temperature sensor 42 operable to determine the temperature of the image source system 40. In an embodiment, the temperature sensor 42 is a thermistor attached to the image source system 40.

In an example embodiment, the thermistor or multiple thermistors are in electrical connection with the electronics 65 of the image source system 40, or are otherwise in the same temperature environment of the image source system 40 such that the temperature of one of the thermistors is able to measure the temperature of the image source system 40. The thermistor or multiple thermistors are also in electronic communication such that the processor 75 can receive the signal from the thermistor.

The example embodiments of this wearable augmented reality system enable extremely compact, planar, and power efficient display systems. The pixel-power addressable characteristics of self-emitting microdisplays provide benefits including lower power consumption, decreased heating of the display and discomfort to the user, relaxed requirements on heat sinking and thermal management which could otherwise increase system bulk, and lower requirements for battery power resulting in more compact or longer-lasting batteries. This wearable optical system can be used as described to enable a projected image to lay on the imaging light guide's near-eye display, which transparently allows the user to view both the projected image as well as the surrounding real-world view behind it.

In an exemplary embodiment, pixel-addressable power requirements of the image source system 40 require power only as needed to generate illumination corresponding to the output power of pixels composing the images. The drive electronics 65 use some power for clocking and image formatting functions but this amount of power is generally substantially less that the drive power provided to the individually addressable components 516, 536, 546, 566. Another example embodiment has a configuration for a compact near-eye display system wherein the image source system 40 and associated drive electronics 65 are mounted along the temple of the glasses 30, configuring the system in such a way to resemble conventional eye-wear. Other configurations of the image source system 40 and drive electronics 65 are possible, for example using mirrors to guide the optical path to best match the specific glasses being used.

In an example embodiment, the thermistor data are input to control electronics 75, also herein referred to as a “processor.” In one example embodiment, the processor 75 is programmed to receive the signal from the thermistor relaying the temperature of the image source systems 40. The processor 75 is also pre-programmed with a responsive thermal mitigating protocol. In an example embodiment, the thermal mitigating protocol is stored in the memory 85. In an example embodiment, there is a single predetermined temperature that will trigger the processor 75 to initiate the mitigating protocol. In another example embodiment, there are multiple temperatures that trigger the processor 75 to initiate multiple stages of a mitigating protocol, where each temperature triggers a different level or stage of mitigating response. The different levels of mitigating response are described in more detail below.

In an example embodiment, each pixel of the display can include a plurality of individually addressable components 516, 536, 546, 566. Turning off or reducing the brightness of the individually addressable components 516, 536, 546, 566 within a given pixel of an image will change the brightness or turn off completely the portion of the image corresponding with that pixel. The mitigating protocol is a reduction in brightness of a selection of the individually addressable components 516, 536, 546, 566. In another example embodiment, the mitigating protocol includes eliminating light from a selection of pixels by turning off individually addressable components 516, 536, 546, 566. That is, in the image source system 40, the display pixels each have individual emission, so the brightness of corresponding pixels can be manipulated separately. This allows for the reduction in brightness or the elimination of brightness (by turning off individually addressable components 516, 536, 546, 566) of the image source system 40 to be non-uniformly applied over the image source system 40. This allows at least a portion of the image to remain at a higher brightness, maintaining the same contrast, in those non-altered pixels, to the contrast of the image source system 40 before the mitigating protocol. By “dimming” or decreasing the brightness of a selection of pixels, or by disilluminating/extinguishing a selection of pixels, while allowing a selection of pixels to remain unaltered, the image conveyed to the viewer may be reduced in saturation, but the image would maintain its contrast level with the real-world view in at least a portion of the image.

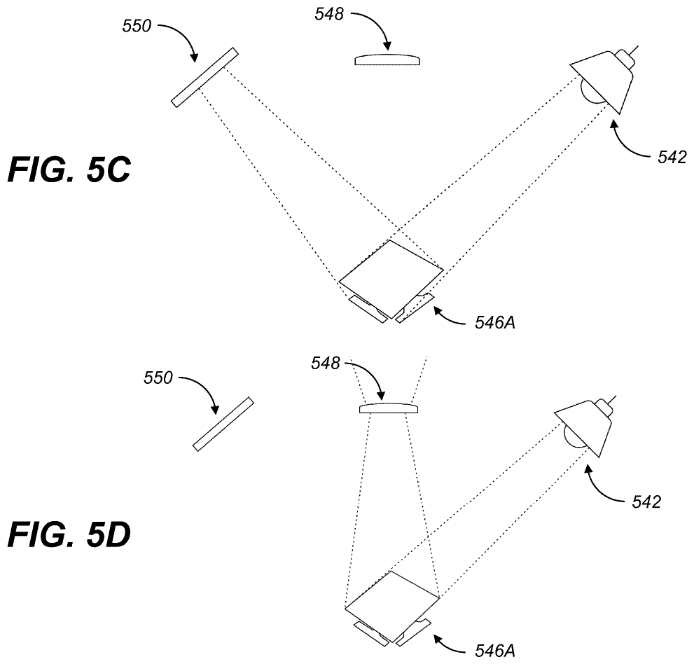

FIG. 8 shows an example of an array of landing page display images 100. The features of the landing pages are shown as illuminated pixels which are overlayed on a white background which represents unilluminated pixels. In application this white background may represent a transparent window into a real-world view. In other words, the landing pages shown in FIG. 8 represent the pixel illuminations, where white areas in FIG. 8 represent areas of unilluminated pixels which would correspond to areas on the near-eye display which would not feature any projected overlay, and black areas in FIG. 8 represent areas of illuminated pixels. A landing screen array 100 such as depicted in FIG. 8 can be arranged as a series of options in a menu, as facets of a movable carousel, or arranged in other organizational structures to facilitate user interfacing. These landing pages have some static features and labels and some areas with variable features. For example, in the Home Screen landing page, the label “Home” is a static label. The various graphic elements of these screens can be static or variable.

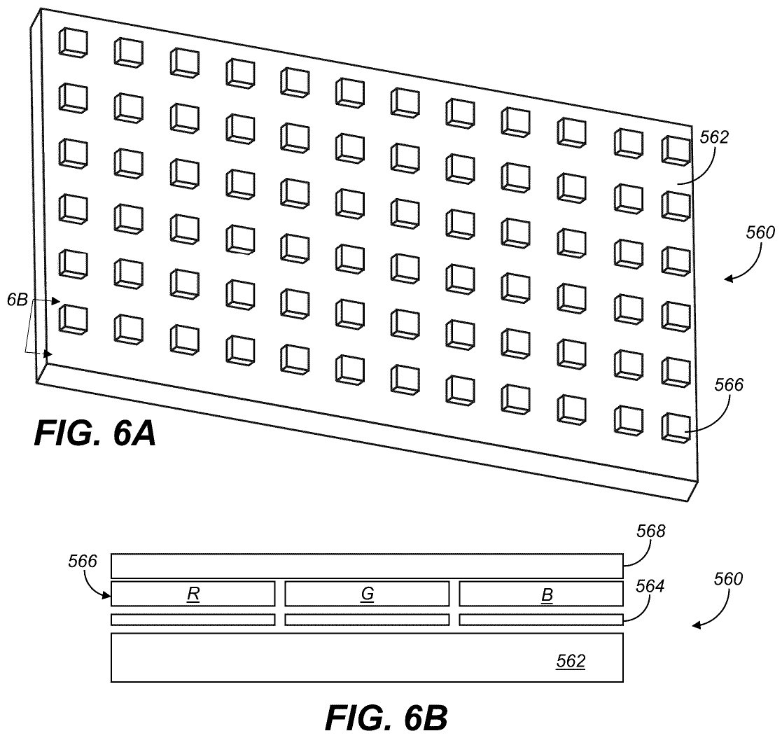

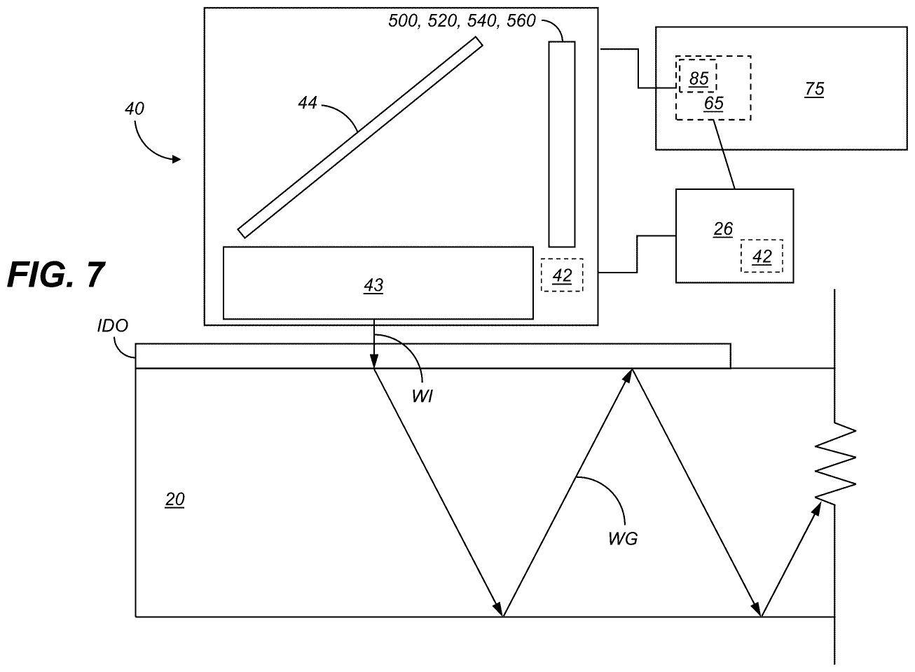

In one example embodiment of the present disclosure, the processor 75 is programmed to recognize or store in memory the locations (and corresponding pixels) of the peripheral edges of the shapes of the various graphic elements in the image. These edges would define a space, for example, the edges of the individual letters in the static label “Home,” shown in FIG. 8, FIG. 9, and FIG. 10, would define a space within the outer peripheral edge of the letters “Home”. The processor 75 is able to recognize or store peripheral edges of graphic elements by a program that reads the peripheral boundaries of shapes in a digital image, or alternatively the information about which pixels are peripheral can be encoded into the digital image data itself. By identifying the outer peripheral boundary of a graphic element, the processor 75 will also recognize the interior area of each graphical element, contained in the interior space defined by the peripheral boundary. Additionally, the processor 75 is capable of recognizing, by either of the methods described above, a defined space 212, 214, 216, that contains multiple graphic elements. For example, the processor 75 can distinguish that each letter of the word “Home” is within a larger grouping 212 of the word “Home,” and identify a section of the image as the area of that label.

FIG. 9 shows an enlarged example of a home screen landing page 150. As in all the presented drawing figures, the white background represents areas of unilluminated pixels. In one example embodiment, the unilluminated pixels are on the image source system 40.

FIG. 10 shows an embodiment of the present disclosure with the “Home” label element of a home screen landing page 200. In this embodiment of the present disclosure, the mitigating protocol 202 includes maintaining illumination and contrast level of the pixels on the peripheral boundary 210 of the shape of the letters comprising the wore “Home,” identified by the processor 75. The peripheral boundary pixels 210 of the letters in “Home” are not dimmed or disilluminated. In one example embodiment, the peripheral edge of each letter in “Home” is given a defined thickness greater than one pixel, such that the outer boundary of the graphic element is defined with an outline where the line has a predetermined thickness. The optimal thickness of the line can be altered to maximize aesthetic and legibility value of the graphic element. The embodiment depicted in FIG. 10 also includes a repeating pattern of disilluminated pixels 222 and unaltered pixels 220, where the pattern covers the defined interior of the graphic element. The mitigation protocol 202 shown in FIG. 10 will reduce the overall power output of the image, as those individual pixels will no longer output energy (i.e., light energy or heat energy) at all, where the unaltered pixels 222 will maintain the same energy output and contrast level with the background real-world view.

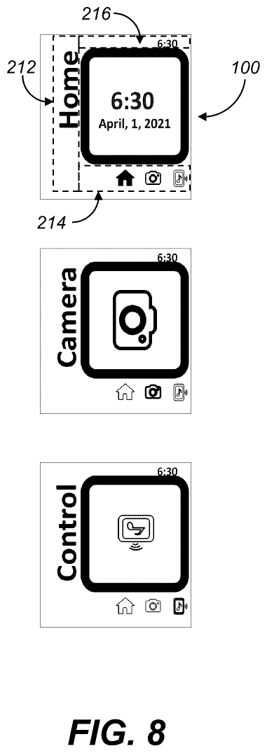

FIG. 11 illustrates the “Home” label element of a home screen landing page 200, showing the mitigation protocol 204 in application with the “Home” label. In this embodiment, the peripheral boundary 210 of the letters in “Home” is maintained, to a certain thickness, at the same brightness and contrast level. The interior of the graphic elements features a repeating pattern of disilluminated pixels 222 and unaltered pixels 220, similar to the embodiment in FIG. 10. However, in this embodiment, the interior pattern features a balanced number of illuminated pixels 220 and disilluminated/extinguished pixels 222. In one example embodiment, every other pixel is disilluminated/extinguished. In other examples, a random or pseudo random arrangement of pixels are disilluminated/extinguished, e.g., 30%, 40%, 50%, 60%, 70%, etc., of the pixels can be disilluminated.

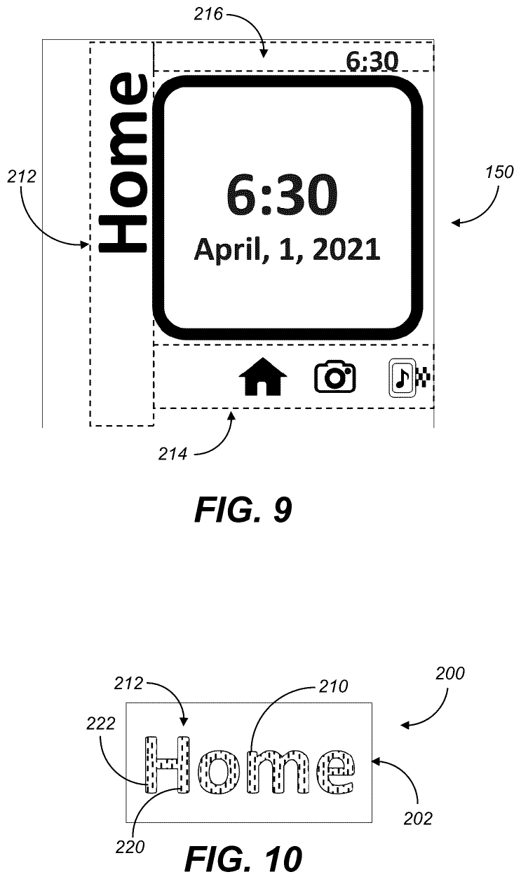

FIG. 12 illustrates the “Home” label element of a home screen landing page 200 showing another mitigation protocol 206 in application with the “Home” label. In one example embodiment, as in previously described embodiments, the peripheral boundary 210 is maintained, to a certain thickness, at the same brightness and contrast level. In another example embodiment, the peripheral boundary 210 is maintained, to a certain thickness, at a reduced brightness and contrast level. The interior of the graphic element features a pattern of unaltered pixels 220 and dimmed pixels 224. This embodiment maintains unaltered contrast with the background only at the peripheral edge of the graphic element. The interior of the graphic element has a mix of dimmed or attenuated pixels, where the energy output of the pixels has been lowered but not completely stopped, and illuminated pixels, where the pixels are still emitting energy. Alternatively, the interior of the graphic element can feature a pattern of disilluminated pixels 222 and dimmed pixels 224. This embodiment will lower the energy output of the two-dimensional image source system 40 both by disilluminating/extinguishing a selection of pixels and by reducing the brightness of another selection of pixels, but this embodiment will also maintain contrast with the real-world view by maintaining energy output at the peripheral edge.

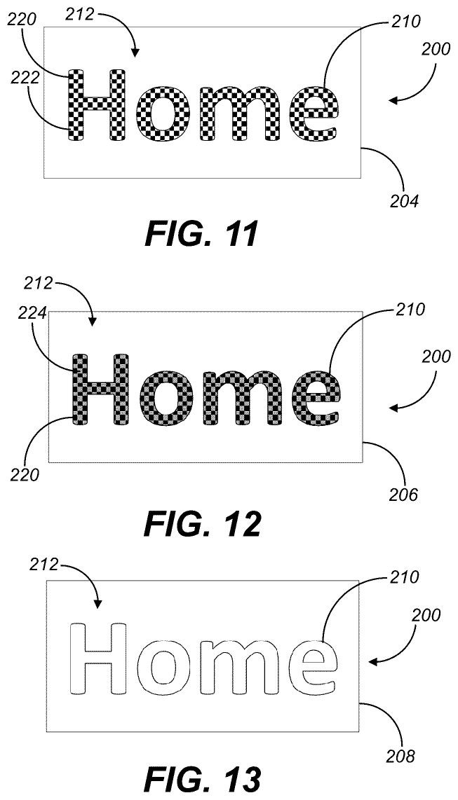

FIG. 13 illustrates the “Home” label element of a home screen landing page 200 and is showing another example embodiment of a mitigation protocol 208 in application with the “Home” label. The peripheral boundary 210 is maintained, to a certain thickness, at the same brightness and contrast level, but the interior of the graphic element is fully disilluminated. This will reduce power output of the display by reducing the interior energy output completely, but will still maintain contrast with the real-world view in at least the peripheral edge of the graphic element. This enables a user to use the least amount of energy while still retaining the ability to easily see the shapes in the near-eye display image by maintaining an optimal level of contrast in brightness levels between the display and the real-world lighting conditions.

It should be understood that any of the described embodiments of mitigating protocols can be used individually as a single mitigating protocol, or, in an alternative embodiment, each of the mitigating protocols are implemented in a succession, with different levels of mitigation triggered by different conditions. For example, in an embodiment, the lowest level of mitigation, i.e., the level with the lowest impact on energy output reduction, will be triggered by a pre-determined temperature threshold signal received by the processor 75 from a thermistor. The next highest level of mitigation will be triggered by the processor 75 if the temperature is still equal to or higher than the threshold temperature after a certain pre-determined amount of time. This level of mitigation will have an even lower overall energy output than the first level of mitigation, and will therefore have a greater impact on energy output reduction. The present disclosure includes any level or combination of levels of mitigating response where the reduction in energy output is non-uniform between adjacent pixels in a display.

It should also be understood that the “energy” referred to herein can refer to either light energy or heat energy, and that a reduction in energy output of the two-dimensional image source system 40 will reduce a power consumption of the image source system 40, as well as reduce overall light energy and heat energy emitted from the image source system 40. This enables the present disclosure to be used as a heat-management system as well as a power conservation system, as well as a tool to reduce overall light emission of the image source system 40. In an example embodiment, the mitigation protocol can be triggered by a battery level dropping below a certain level and sending a signal to the processor 75. In another example embodiment, the mitigation protocol can be triggered by a user manually initializing it, as a part of a larger system protocol to conserve battery power or for any other reason.

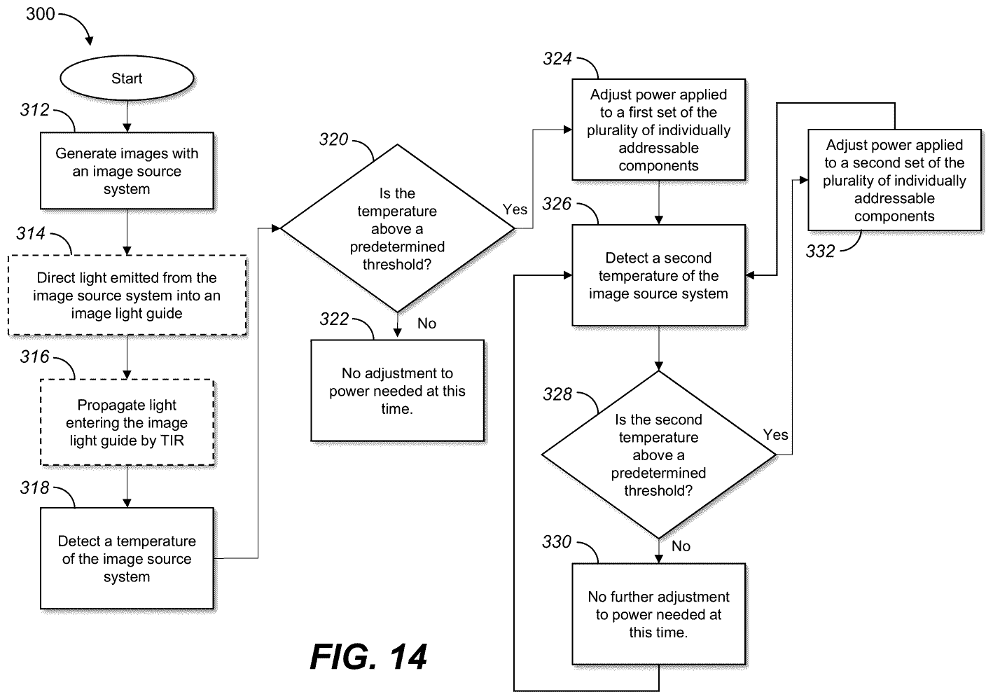

In an example embodiment as provided in FIG. 14, a method of thermal control of an augmented reality near-eye display 300 may be performed. At the start of the method, images are generated with an image source system 40 according to step 312. The image source system 40 may comprise a plurality of individually addressable components 516, 536, 546, 566 forming an array of pixels. According to the optional next step 314, light emitted from the image light source 40 is directed into an optically transmissive image light guide 20, wherein the optically transmissive image light guide 20 comprises an optically transmissive substrate S having front and back surfaces, an in-coupling diffractive optic IDO, and an out-coupling diffractive optic ODO located along the optically transmissive substrate. As provided in optional step 316, light propagates within the optically transmissive substrate S by internal reflections from the front and back surfaces to the out-coupling diffractive optic ODO, wherein the internally reflected light is conveyed to an eyebox E within which the images generated by the image source system 40 are viewable as virtual images. Next, according to step 318, a temperature within the image source system 40 is detected. In one example embodiment, a temperature sensor 42, for example a thermistor, detects the temperature. As provided in step 320, it is determined whether the temperature is above a first predetermined threshold. In an example embodiment, this determination is made via a processor 75. In one example embodiment, the first predetermined threshold is a temperature of 50° C. In another example embodiment, the first predetermined threshold is a temperature of 38° C. or 46° C. If the temperature of the image source system 40 is below the first predetermined threshold, no adjustment to the power output of the plurality of individually addressable components 516, 536, 546, 566 is needed, according to step 322. However, if the temperature is above the first predetermined threshold, then the power applied to a first set of the plurality of individually addressable components 516, 536, 546, 566 is adjusted according to step 324. In an example embodiment, when the power is adjusted, the amount of light emitted from a first set of pixels 220, 222 is modulated, whereby heat generation by the image source system 40 is reduced. In another example embodiment, when the power is adjusted, no light is emitted from a first set of pixels 220, 222, whereby heat generation by the image source system 40 is reduced. In one example embodiment, mitigation protocol 206 as shown in FIG. 12 may be implemented.

In one example embodiment, the step 324 of adjusting power applied to the first set of the plurality of individually addressable components 516, 536, 546, 566 comprises selecting a non-uniform distribution of pixels 220, 222. In another example embodiment, the step 324 of adjusting power applied to the first set of the individually addressable components 516, 536, 546, 566 comprises selecting a uniform distribution of pixels 220, 222. That is, the plurality of individually addressable components 516, 536, 546, 566 having attenuated power correspond to predetermined portions of an image conveyed to the eyebox E. For example, in one configuration, every other pixel 220, 222 may have a reduced brightness or be completely disilluminated. In another example embodiment, every two pixels may have a reduced brightness or be completely disilluminated. In yet another example embodiment, the first set of the plurality of individually addressable components 516, 536, 546, 566 having attenuated power may correspond to a single color within the array of pixels 220, 222 comprising an image. In a further example embodiment, a single LED color or a set of certain LED colors within a single pixel or within a plurality of pixels has a reduced brightness or is completely disilluminated. For example, if each pixel was associated with 4 LEDs (1 Blue, 1 Green and 2 Red) in response to the temperature trigger, the blue and green LEDs could be reduced in brightness or completely disilluminated leaving only the green LEDs illuminated. This would reduce power consumption and heat within those pixels by approximately 75%. In still a further example embodiment, the set of pixels 220, 222 may be within a defined space of the array of pixels. For example, the set of pixels 220, 222 may be within an outer periphery of at least a portion of an image.

According to step 326, in one example embodiment, a second temperature within the image source system 40 is detected. Then in step 328, it is determined whether the second temperature is below a second predetermined threshold. If the second temperature is not above a second predetermined threshold (where the second predetermined threshold is higher than the first predetermined threshold), the processor 75 will not make another adjustment to the power at that time according to step 330. If the second temperature is above the second predetermined threshold, the power applied to a second set of the plurality of individually addressable components 516, 536, 546, 566 is adjusted to modulate amounts of light emitted from a second set of pixels 220, 222 according to step 332, whereby heat generation by the image source system 40 is further reduced. In one example embodiment, mitigation protocol 204 as shown in FIG. 11 may be implemented instead of mitigation protocol 206. Steps 326-332 may be repeated. In particular, if the temperature sensor 42 provides that a third temperature within the image source system 40 is above a third predetermined threshold (where the third predetermined threshold is higher than the second predetermined threshold), the power applied to a third set of the plurality of individually addressable components 516, 536, 546, 566 may be adjusted or the power applied to one or both of the first set or second set of the plurality of individually addressable components 516, 536, 546, 566 may be reduced or eliminated. In one example embodiment, mitigation protocol 202 or 208 may be implemented, depending on the level of heat reduction required. In one example embodiment, the size of the images generated by the image source system 40 is reduced to provide a virtual image that fits within a smaller portion of the field of view. The different temperature thresholds can be evaluated all at the same time, or incrementally. For example, if the third temperature exceeds a third threshold, the system can automatically switch to a mitigation protocol that is commensurate with that level of needed heat reduction. For example, the mitigation protocol can be switched from mitigation protocol 206 to any of mitigation protocols 202, 204, or 208. In one example embodiment, if the first temperature reveals that a higher temperature threshold is exceeded, a mitigation protocol can be implemented to drastically reduce the heat (e.g., mitigation protocol 208 shown in FIG. 13). If, after a predetermined amount of time, another temperature is measured and the heat has been reduced to a relatively high, but acceptable temperature, the mitigation protocol can be stepped down to a different mitigation protocol, for example mitigation protocol 204 as shown in FIG. 11.

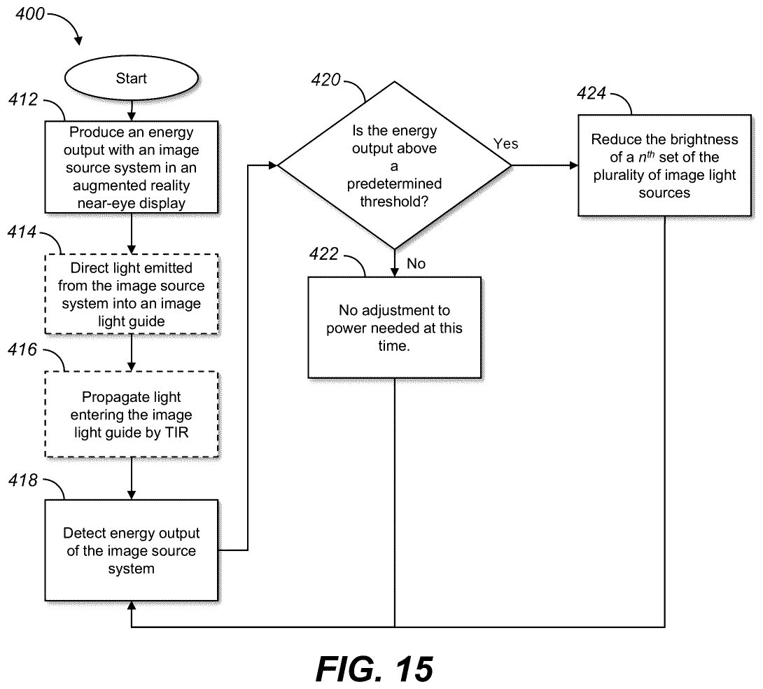

In another an example embodiment as provided in FIG. 15, a method 400 of mitigating an undesired level of energy output in an augmented reality near-eye display system may be provided. According to step 412, an energy output within an image source system 40 in an augmented reality near-eye display system may be produced. The image source system 40 is configured to generate images via a plurality of individually addressable components 516, 536, 546, 566 in an array of pixels. According to optional step 414, the light emitted from the plurality of individually addressable components 516, 536, 546, 566 is directed into an optically transmissive image light guide 20, wherein the optically transmissive image light guide 20 comprises an optically transmissive substrate S having front and back surfaces, an in-coupling diffractive optic IDO, and an out-coupling diffractive optic ODO located along the optically transmissive substrate S. Then, at least a portion of the light diffracted into the optically transmissive substrate S is propagated by internal reflections from the front and back surfaces to the out-coupling diffractive optic ODO, by which the internally reflected light is conveyed to an eyebox within which the images generated by the image source system 40 are viewable according to optional step 416. Next, as provided in step 418, the energy output of the image source system 40 is detected. The energy output in one example embodiment is light energy, while the energy output in another example embodiment is heat energy. In step 420, it is determined whether the energy output is above a first predetermined threshold. If the energy output is not above the first predetermined threshold, then no adjustment to the power is needed at that point in time as provided in step 422. In one example embodiment, the predetermined threshold is a temperature in the range of 40° C. to 45° C. In another example embodiment, the predetermined threshold is a temperature in the range of 45° C. to 50° C. In yet another example embodiment, the predetermined threshold is a temperature in the range of 60° C. to 70° C. If the energy output is not above the predetermined threshold, no adjustment to the power is needed at that time according to step 422. If the energy output is above the predetermined threshold, the power to a first set of the plurality of individually addressable components 516, 536, 546, 566 can be decreased or switched-off according to step 424. For example, the first set of the plurality of individually addressable components 516, 536, 546, 566 can be disilluminated wherein the first set of the plurality of individually addressable components 516, 536, 546, 566 corresponds to a first selection of approximately evenly distributed pixels within an outer peripheral boundary of at least a portion of the image. Alternatively, the first set of the plurality of individually addressable components 516, 536, 546, 566 includes the step of reducing a brightness of the first set of the plurality of individually addressable components 516, 536, 546, 566, where the first set of the plurality of individually addressable components 516, 536, 546, 566 corresponds to a first selection of approximately evenly distributed pixels within an outer peripheral boundary of at least a portion of the image. According to method 400, the steps 418, 420 of detecting the energy output of the image source system 40 and determining whether the energy output is above a first predetermined threshold is repeated. Again, if a processor 75 determines that the energy output is not above the first predetermined threshold, no further adjustment to the power is made at that time according to step 422. If the energy output is above the predetermined threshold, the power applied to a second set of the plurality of individually addressable components 516, 536, 546, 566 is adjusted to reduce the brightness of or to disilluminate the second set of the plurality of individually addressable components 516, 536, 546, 566 corresponding to a second selection of approximately evenly distributed pixels within an outer peripheral boundary of at least a portion of the virtual image as provided in step 424. Steps 418-424 can be repeated to periodically monitor the energy output of the image source system 40 and adjustments in power made to reduce the brightness or disilluminate select sets of pixels 220, 222 until only the outer periphery of at least a portion of the image is conveyed to the eyebox E. For example, the word “Home” as provided in FIG. 13.

Persons skilled in the relevant arts will recognize that example embodiments of the presently disclosed image source system 40 may be utilized without an image light guide to display images.

One or more features of the embodiments described herein may be combined to create additional embodiments which are not depicted. While various embodiments have been described in detail above, it should be understood that they have been presented by way of example, and not limitation. It will be apparent to persons skilled in the relevant arts that the disclosed subject matter may be embodied in other specific forms, variations, and modifications without departing form the scope. spirit, or essential characteristics thereof. The embodiments described above are therefore to be considered in all respects as illustrative, and not restrictive. The scope of the invention is indicated by the appended claims, and all changes that come within the meaning and range of equivalents thereof are intended to be embraced therein.

What is claimed is:

1. An augmented reality near-eye display system, comprising:
an image source system operable to generate image-bearing light beams, the image source system comprising a plurality of individually addressable components;
a temperature sensor operable to detect a temperature within the image source system; and
a processor and non-transitory computer-readable memory configurated to execute and store a set of computer-readable instructions that when executed by the processor are configured to selectively drive each of the plurality of individually addressable components based on the temperature of the image source system.

2. The augmented reality near-eye display system of claim 1, further comprising:
an optically transmissive image light guide operable to propagate the image-bearing light beams via total internal reflection,
an in-coupling diffractive optic formed along the image light guide, wherein the in-coupling diffractive optic is operable to diffract at least a portion of the image-bearing light beams into the image light guide in an angularly encoded form; and
an out-coupling diffractive optic formed along the image light guide, wherein the out-coupling diffractive optic is operable to direct at least a portion of the image-bearing light beams from the image light guide in an angularly decoded form.

3. The augmented reality near-eye display system of claim 1, wherein the image source system is a self-emitting microdisplay system, wherein the plurality of individually addressable components comprises a plurality of self-emitting light sources configured to emit light as a function of power applied to each self-emitting light source.

4. The augmented reality near-eye display system of claim 3, wherein the plurality of self-emitting light sources includes a semiconductor micro light emitting diode (uLED) array.

5. The augmented reality near-eye display system of claim 3, wherein the plurality of self-emitting light sources includes an OLED array.

6. The augmented reality near-eye display system of claim 1, wherein the image source system is a projector energizable to emit a set of angularly related beams.

7. The augmented reality near-eye display system of claim 6, wherein each of the plurality of individually addressable components comprises a transistor or an electrode.

8. The augmented reality near-eye display system of claim 1, wherein the image source system is supported by a temple member of a frame.

9. The augmented reality near-eye display system of claim 1, wherein the temperature sensor is operable to selectively alter power to a first set of the plurality of individually addressable components corresponding to a first set of pixels in at least a first portion of an image generated by the processor.

10. The augmented reality near-eye display system of claim 9, wherein the plurality of individually addressable components correspond to one or more pixels in an array of pixels, wherein a first portion of the array of pixels defines a peripheral region of the array of pixels, and a second portion of the array of pixels defines an inner region of the array of pixels, and wherein the first set of pixels is within the first portion of the array of pixels.

11. The augmented reality near-eye display system of claim 10, wherein the peripheral region of the array of pixels comprises approximately 20% of the array of pixels.

12. The augmented reality near-eye display system of claim 9, wherein the first set of pixels are a non-uniform distribution of pixels within the plurality of individually addressable components.

13. The augmented reality near-eye display system of claim 9, wherein the first set of pixels corresponds to a single color emitted by the plurality of individually addressable components.

14. The augmented reality near-eye display system of claim 9, wherein the first set of pixels is within a defined space within the plurality of individually addressable components.

15. The augmented reality near-eye display system of claim 9, wherein more than 50% of the plurality of individually addressable components corresponding to one or more pixels in the first set of pixels are altered, and wherein a remaining percentage of the plurality of individually addressable components are not altered.

16. The augmented reality near-eye display system of claim 1, wherein the temperature sensor is a thermistor.

17. A method of thermal control of an augmented reality near-eye display system, comprising:
generating images with an image source system, the image source system comprising a plurality of individually addressable components;
detecting a first temperature within the image source system; and
adjusting power applied to a first set of the plurality of individually addressable components when the first temperature of the image source system is above a predetermined threshold to modulate light emitted from a first set of pixels corresponding to the first set of the plurality of individually addressable components, whereby heat generation by the image source system is reduced.

18. The method of thermal control of claim 17, further comprising:
directing light emitted from image light source system into an optically transmissive image light guide, wherein the image light guide comprises an in-coupling diffractive optic and an out-coupling diffractive optic arranged along the image light guide;
propagating image-bearing light entering the optically transmissive image light guide through the in-coupling diffractive optic to the out-coupling diffractive optic, wherein the image-bearing light is conveyed to an eyebox within which the images generated by the two-dimensional image source system are viewable.

19. The method of claim 17, further comprising the step of detecting a second temperature within the image source system; and adjusting power applied to a second set of the plurality of individually addressable components when the second temperature of the two-dimensional image source system is above a predetermined threshold to modulate amounts of light emitted from a second set of pixels corresponding to the second set of the plurality of individually addressable components, whereby heat generation by the image source system is reduced by a greater degree than the first temperature.

20. The method of claim 19, further comprising the step of detecting a third temperature within the image source system; and adjusting power applied to a third set of the plurality of individually addressable components when the third temperature of the image source system is above a predetermined threshold to modulate amounts of light emitted from a third set of pixels corresponding to the third set of the plurality of individually addressable components, whereby heat generation by the image source system is reduced by a greater degree than the first temperature and the second temperature.

21. The method of claim 17, further comprising the step of adjusting a size of the images generated by the image source system to utilize fewer of the plurality of individually addressable components.

22. The method of claim 17, wherein the step of adjusting power applied to the first set of the plurality individually addressable components when the first temperature is above a predetermined threshold further comprises the step of altering power to the first set of the plurality of individually addressable components corresponding to a non-uniform distribution of pixels.

23. The method of claim 17, wherein the step of adjusting power applied to the first set of the plurality individually addressable components when the first temperature is above a predetermined threshold further comprises the step of altering power to the first set of the plurality of individually addressable components corresponding to a single color within the array of pixels.

24. The method of claim 17, wherein the step of adjusting power applied to the first set of the plurality individually addressable components when the first temperature is above a predetermined threshold further comprises the step of altering power to the first set of the plurality of individually addressable components corresponding to a first set of pixels within a defined space of the array of pixels.

25. The method of claim 17, wherein the step of generating images with an image source system further comprises the step of using a self-emitting microdisplay system as the image source system, wherein the plurality of individually addressable components comprises a plurality of self-emitting light sources configured to emit light as a function of power applied to each self-emitting light source.
